(19) United States
(12) Patent Application Publication
(10) Pub. No.: US 2024/0327300 A1
(43) Pub. Date: Oct. 3, 2024

(54) CERAMIC SYNTHESIS THROUGH SURFACE COATING OF POWDERS

(71) Applicant: Applied Materials, Inc., Santa Clara, CA (US)

(72) Inventors: Nitin Deepak, Thane (IN); Katherine Woo, Santa Clara, CA (US); Ryan Sheil, Santa Cruz, CA (US); Juan Carlos Rocha-Alvarez, San Carlos, CA (US); Jennifer Y. Sun, Fremont, CA (US)

(73) Assignee: Applied Materials, Inc., Santa Clara, CA (US)

(21) Appl. No.: 18/128,124

(22) Filed: Mar. 29, 2023

(51) Int. Cl. C04B 35/628; C04B 35/626

(52) U.S. Cl. CPC C04B 35/62805; C04B 35/62665; C04B 35/62836; C04B 2235/666; C04B 2235/85; C04B 2235/9669

(57) ABSTRACT

Exemplary processing methods may include providing a powder to a processing region of a processing chamber. The methods may include providing one or more deposition precursors to the processing region. The methods may include generating plasma effluents of the one or more deposition precursors. The methods may include depositing a layer of material on the powder in the processing region. The layer of material may include a corrosion-resistant material. A temperature within the processing chamber is maintained at less than or about 700° C.

### TECHNICAL FIELD

The present technology relates to coating processes and semiconductor chamber components. More specifically, the present technology relates to modified components and component materials.

### BACKGROUND

Integrated circuits are made possible by processes which produce intricately patterned material layers on substrate surfaces. Producing patterned material on a substrate requires controlled methods of formation and removal of exposed material. Deposition and removal operations may include producing a local plasma in a processing region of a semiconductor processing chamber, for example, between a showerhead or gas distributor and a substrate support. Components of the semiconductor processing chamber may be or include a sintered composite material. Where the sintered composite material is exposed to corrosive species on a repeated basis, degradation of the components and contamination of substrates being processed may occur. Accordingly, a top coating may be provided to protect the underlying component from corrosion. However, the top coating may eventually be exhausted and require replacement.

Thus, there is a need for improved systems and system components that can be used to produce high quality devices and structures. These and other needs are addressed by the present technology.

### SUMMARY

Exemplary processing methods may include providing a powder to a processing region of a processing chamber. The methods may include providing one or more deposition precursors to the processing region. The methods may include generating plasma effluents of the one or more deposition precursors. The methods may include depositing a layer of material on the powder in the processing region. The layer of material may include a corrosion-resistant material. A temperature within the processing chamber is maintained at less than or about 700° C.

In some embodiments, the powder may be or include a ceramic-containing powder. The powder may be or include aluminum oxide (Al₂O₃), yttrium oxide (Y₂O₃), magnesium oxide (MgO), titanium oxide (TiO₂), aluminum nitride (AlN), or silicon nitride (Si₃N₄). The layer of material may be or include an oxide. The oxide may be or include aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), or zirconium oxide (ZrO₂). The layer of material may be or include a nitride. The nitride may be or include aluminum nitride (AlN), silicon nitride (SiN), tantalum nitride (TaN), titanium nitride (TiN), or zirconium nitride (ZrN). The methods may include, subsequent to depositing the layer of material, annealing the powder. The powder may be annealed in a pressure-controlled oxygen-containing environment, inert environment, or active gas environment. The methods may include, subsequent to depositing the layer of material, sintering the powder to form a component for semiconductor processing.

Some embodiments of the present technology may encompass processing methods. The methods may include providing a ceramic-containing powder to a processing region of a processing chamber. The methods may include depositing a layer of material on the ceramic-containing powder in the processing region. The layer of material may be a corrosion-resistant material. Depositing the layer of material may include exposing the ceramic-containing powder to plasma effluents of a first precursor, purging the processing region, and exposing the ceramic-containing powder to plasma effluents of a second precursor. The layer of material may include reaction products of the plasma effluents of the first precursor and the plasma effluents of the second precursor. The methods may include sintering the ceramic-containing powder to form a component for semiconductor processing. The layer of material may be dispersed throughout the component.

In some embodiments, the ceramic-containing powder may be aluminum oxide (Al₂O₃), yttrium oxide (Y₂O₃), magnesium oxide (MgO), titanium oxide (TiO₂), aluminum nitride (AlN), or silicon nitride (Si₃N₄). The first precursor may be or include either a metal precursor or an oxygen or nitrogen precursor. The second precursor may be include either a metal precursor or an oxygen or nitrogen precursor. The first precursor and the second precursor may be or include different precursors. Either the first precursor or the second precursor may include fluorine. The layer of material may be or include an oxynitride. A temperature within the processing chamber may be maintained at less than or about 700° C. A pressure within the processing chamber may be maintained at less than or about 50 mTorr. The layer of material may be characterized by a thickness of less than or about 10 nm.

Some embodiments of the present technology may sintered semiconductor components. The components may include a ceramic primary phase defining a plurality of grain boundaries. The components may include a secondary phase confined to the plurality of grain boundaries. The secondary phase may be deposited on the ceramic primary phase prior to sintering a coated powder to form the sintered semiconductor component. The secondary phase may be or include a corrosion-resistant material.

In some embodiments, the coated powder may be prepared by a process including exposing a ceramic-containing powder in a processing region to plasma effluents of a first precursor, purging the processing region, and exposing the ceramic-containing powder to plasma effluents of a second precursor to form a layer of material on the ceramic-containing powder. The layer of material may include reaction products of the plasma effluents of the first precursor and the plasma effluents of the second precursor. The layer of material may form the secondary phase during sintering of the coated powder.

Such technology may provide numerous benefits over conventional systems and techniques. For example, the methods and systems may provide a coated powder, a sintering blend, and a sintered material, exhibiting improved compatibility with plasma processing applications. For example, a powder may be chemically reduced to remove a passivation layer on the grains of the powder. In this way, a layer of material may be a coated directly onto a powder, for example, by atomic layer deposition. By sintering one or more coated powders, a sintering blend may permit the forming of a sintered material with tailored thermal, mechanical, and/or chemical properties. As such, the sintered material may exhibit improved thermal, mechanical, and/or chemical properties at elevated temperatures, including temperatures at which semiconductor processing operations are undertaken. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic view of an exemplary processing chamber according to some embodiments of the present technology.

FIG. 2 shows exemplary operations in a deposition method according to some embodiments of the present technology.

FIG. 3 show schematic views of a powder during operations in a deposition method according to some embodiments of the present technology.

FIG. 4 show schematic views of an exemplary processing chamber component formed the method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As part of semiconductor processing technology, deposition and removal operations may include producing a local plasma in a processing region of a semiconductor processing chamber, for example, between a showerhead or gas distributor and a substrate support. Components of the semiconductor processing chamber may be or include a sintered composite material. In order to protect the sintered composite material during operations using plasma, a top coating may be provided to protecting the underlying sintered composite material. The top coating may be a combination of materials, such as metal oxides. A first metal oxide may be deposited on the sintered composite material to promote adhesion between the sintered composite material and a second metal oxide that is corrosion-resistant. However, the top coating may be prone to degradation and/or deterioration during operations using plasma. Eventually, the top coating may be exhausted and the plasma may corrode the sintered composite material.

Conventional technologies have approached this limitation by controlling plasma operating conditions, for example, operating pressure, plasma power, duty cycle, or pulse frequency, which may restrict the operational window. Alternatively, conventional technologies may intermittently replace the top coating in order to maintain the corrosion protection, which require maintenance intervals during processing. The present technology may overcome these limitations by implementing improved deposition methods to remove a native passivation layer from the grains of the powder, which may permit deposition of materials directly onto the grains of the powder, for example, by atomic layer deposition. In addition, by sintering or pressing a coated powder, the distribution of corrosion-resistant material may be uniformly distributed through a sintered component, and may thereby reduce the potential for corrosion of the sintered component and extend the lifetime of the component with less maintenance intervals. This may enable preparation of coated powders for fabricating a variety of improved sintered components, including, but not limited to, plasma processing chamber components that exhibit improved thermal, mechanical, and chemical properties at conditions used for semiconductor processing. As a result, sintered components may be implemented in semiconductor processing chambers that are exposed to plasma operations.

After describing general aspects of a chamber according to embodiments of the present technology in which plasma processing may be performed, specific methodology and component configurations may be discussed. It is to be understood that the present technology is not intended to be limited to the specific films and processing discussed, as the techniques described may be used to improve a number of film formation processes, and may be applicable to a variety of processing chambers and operations.

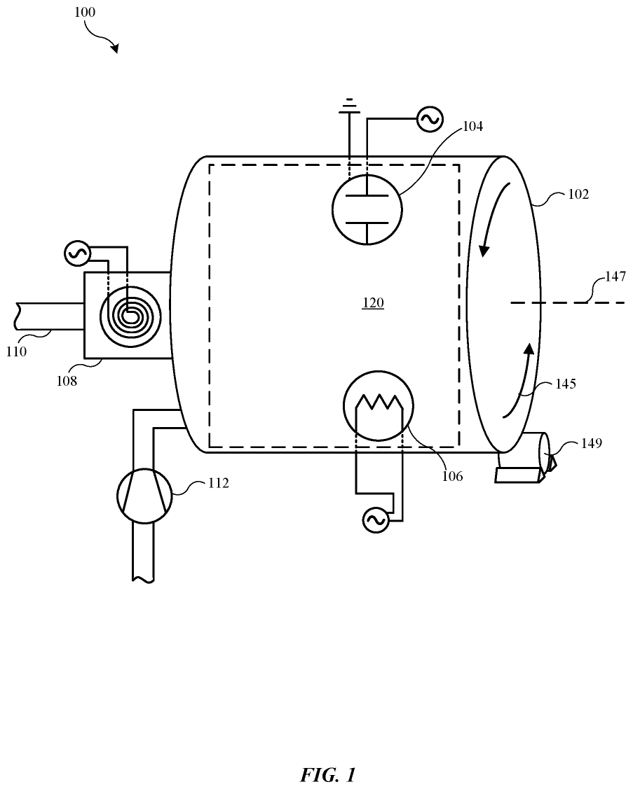

FIG. 1 shows a schematic view of an exemplary processing chamber 100 according to some embodiments of the present technology. The figure may illustrate an overview of a system incorporating one or more aspects of the present technology, and/or which may perform one or more operations according to embodiments of the present technology. Additional details of chamber 100 or methods performed may be described further below. Chamber 100 may be utilized to form coated powders according to some embodiments of the present technology, although it is to be understood that the methods may similarly be performed in any chamber within which film formation may occur. For example, while the chamber 100 is illustrated in a horizontal rotating configuration, alternative embodiments may include a fluidized bed configuration or a plasma powder synthesis system. The processing chamber 100 may include a chamber body 102, a plasma system 104 inside the chamber body 102, a temperature control system 106, and a remote plasma system 108 coupled with the chamber body 102 and configured to provide plasma effluents to a processing region 120 of the chamber body 102.

A powder may be provided to the processing region 120 through a material feedthrough, such as a port or conduit, which may be sealed for processing using a slit valve, gate valve, or door. The powder may be mechanically mixed during processing. To that end, the processing region 120 or the chamber body 102 may be rotatable, as indicated by the arrow 145, about an axis 147, for example, by an electromechanical rotating element 149. Electromechanical rotating element 149 may be configured to rotate one or more structures internal to the chamber body 102, for example, by rotating the chamber body 102 about the axis 147. Alternatively, the powder may be mixed and suspended in the processing region 120 by convective action of gases introduced during a deposition process, for example, by fluidization that may be controlled to limit entrainment and powder loss.

Precursors, as described below, may be provided to the chamber 100 through a gas supply system 110. While FIG. 1 illustrates a single inlet for the gas supply system 110, the chamber 100 may include multiple gas inlets coupled with the chamber body 102 at one or more locations. For example, a plasma precursor may be introduced to the chamber body through the remote plasma system 108, while a second gas inlet may provide gases for which plasma dissociation would negatively impact the deposition process. Gases may be removed from the chamber body 102 by a gas removal system 112. The gas removal system may 112 include a vacuum system, configured to facilitate reduced pressure operation during deposition processes and to evacuate the chamber to remove process effluents and unreacted process gases. Measurement and control systems may be coupled with the chamber to measure operating pressure in one or more places, such as in the gas supply system 110, the gas removal system 112, or in the processing region 120. In another example, the temperature control system 106 may include temperature sensors and a heating element configured to provide heat to the processing region 120 or to remove heat from the processing region 120. In this way, the chamber 100 may implement controlled deposition and removal processes, such as plasma etching and removal, and atomic layer deposition.

As part of implementing plasma processing of powders in the chamber 100, in accordance with the methods described below, the plasma system 104 may be configured to form a plasma within the processing region 120. The plasma system 104 may be or include an indirect plasma system, such as an RF capacitively-coupled plasma, configured to form a plasma within the processing region 120 by generating sufficiently strong electric fields internal to the chamber body 102. In some embodiments, the plasma system 104 may be or include a direct plasma system, such that one or more electrode surfaces are disposed within the chamber body. In this way, the processing region 120 may be defined between a live electrode and a reference ground electrode of the plasma system 104. The plasma system 104 may also include control systems and power supply systems, such as impedance matching circuits and 13.56 MHz RF power supplies.

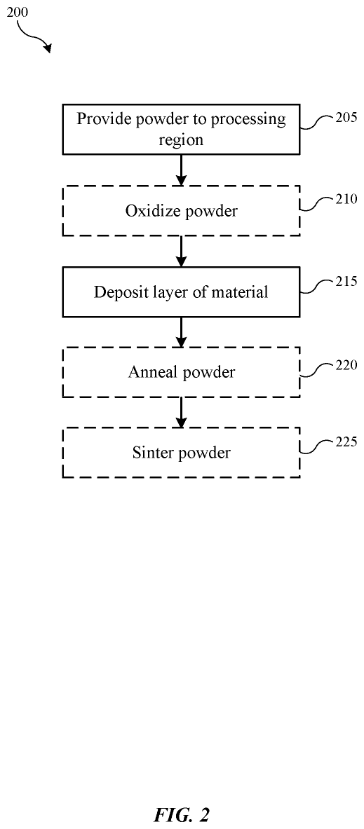

Similarly, the remote plasma system 108 may be or include a direct plasma system or an indirect plasma system, such as an inductively coupled RF plasma system or a capacitively coupled RF plasma system, which may be configured to decompose a precursor into plasma effluents that can be provided to the processing region 120. For example, the gas supply system 110 may include a quartz inlet tube coupled with a feedthrough to the chamber body 102. In such an arrangement, the remote plasma system 108 may be or include an ICP or a CCP system disposed external to the quartz inlet tube and configured to form a plasma within the quartz inlet tube. As further described in reference to FIG. 2, the precursor may include an inert carrier gas and a reaction precursor that may be or include a vapor or a gas. In this way, the remote plasma system 108 may form an indirect plasma in the precursor and may decompose the precursor. The decomposed precursor may be or include plasma effluents, which may be or include carrier gas, unreacted precursor, and plasma generated species. The plasma generated species may serve as reactants in a chemical reaction mediated deposition process, such as atomic layer deposition. As with the plasma system 104, remote plasma system 108 may also include control systems and power supply systems, such as impedance matching circuits and 13.56 MHz RF power supplies.

The temperature control system 106 may be configured to maintain an internal temperature in the processing region in accordance with a processing method. For example, as part of atomic layer deposition, a deposition substrate, such as a powder, may be heated to a reaction temperature at which a particular reaction product is favored. In an illustrative example, a surface reaction that forms a layer of material on the deposition substrate may be thermodynamically favored at an elevated temperature. As such, the temperature control system 106 may provide heat to the processing region. In some embodiments, the temperature control system may at least partially integrated into the plasma system 104. For example, an electrode of the plasma system 104 may incorporate heating and/or cooling elements, permitting the plasma system to operate within a range of operating temperatures.

In some embodiments, the chamber 100 may be configured to prepare coated powders for which the grains of the powder are coated with one or more layers of material. As described in reference to methods and systems, below, the chamber 100 may permit the preparation of improved coated ceramic-containing powders, which may be incorporated into sintering blends and sintered materials. Such sintered materials may exhibit improved thermal, mechanical, and/or chemical properties at processing conditions that are characteristic of plasma deposition and removal operations as part of semiconductor processing.

FIG. 2 shows exemplary operations in a deposition method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

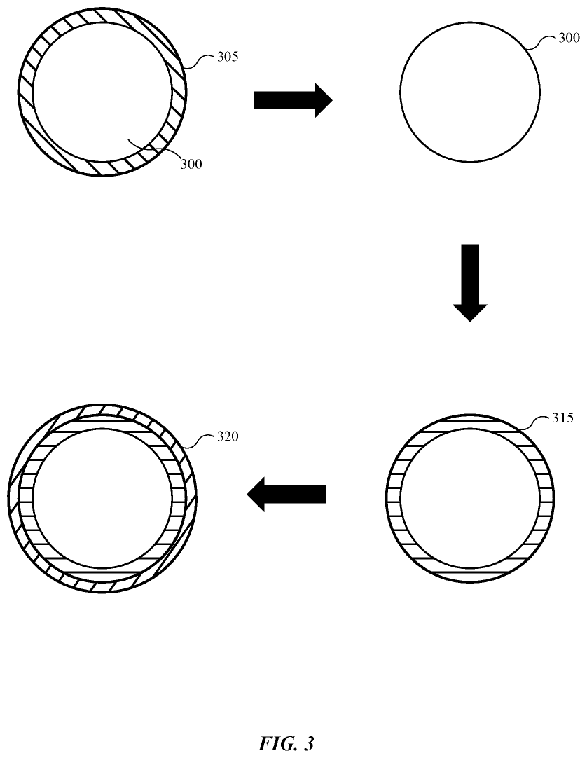

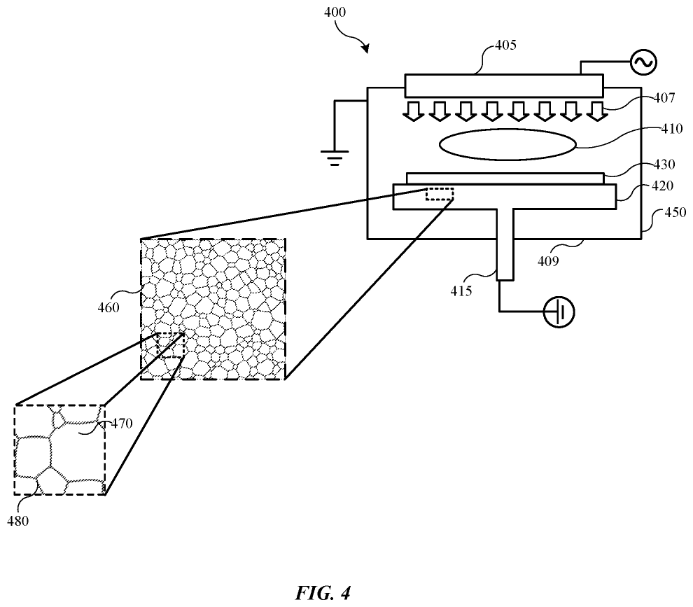

Method 200 describes operations shown schematically in FIG. 3, the illustrations of which will be described in conjunction with the operations of method 200. FIG. 4 illustrates an exemplary semiconductor processing system incorporating materials produced according to some embodiments of the method 200. It is to be understood that FIGS. 3-4 illustrate only partial schematic views, and a processing system may include subsystems as illustrated in the figures, as well as alternative subsystems, of any size or configuration that may still benefit from aspects of the present technology.

FIG. 3 show schematic views of a powder 300 during operations of the deposition method 200 according to some embodiments of the present technology. In some embodiments, the method 200 may include one or more operations preceding those illustrated in FIG. 2. For example, one or more processes may be implemented to form the powder 300 from a feedstock material. For example, the powder 300 may be formed by chemically converting an oxide to a nitride, and may be cleaned, for example, by baking, etching, or degreasing. Examples of nitride synthesis may include, but are not limited to, carbo-thermal nitridization and/or direct nitridization. Furthermore, the powder 300 may be introduced into a processing chamber, such as the chamber 100, bearing a passivation layer 305. For example, the powder 300 may be or include aluminum nitride, which, through exposure to oxygen during cleaning or through exposure to air at ambient conditions, may develop an oxide passivation layer.

Method 200 may include additional operations prior to initiation of the listed operations. For example, additional processing operations may include preparing a particle, for example, by ball milling a material feedstock to prepare a powder of a characteristic size. As illustrated in FIG. 3, method 200 may include removing a passivation layer, such as a native oxide or surface oxide, prior to coating the particle. Removing the passivation layer may include providing hydrogen to the processing region of the chamber. Hydrogen may permit a hydrogen plasma, a hydrogen-rich plasma, or a trace-hydrogen plasma to be formed in the processing region, as an approach to chemically reducing the passivation layer 305. The hydrogen may be provided to the processing region of the chamber with an inert carrier gas. In plasma systems, inert carrier gases, also referred to as “forming gases”, facilitate plasma ignition and control of plasma conditions. For example, providing the hydrogen with a given inert gas fraction may permit the plasma to operate under controlled plasma conditions, such as ionization fraction, ion temperature, or electron temperature. Subsequent introducing hydrogen into the processing region, the method 200 may include striking a plasma in the processing region. The plasma may be or include a hydrogen plasma, and as such it may include energetic plasma species, such as hydrogen ions, hydrogen radicals, or metastable diatomic hydrogen. The hydrogen plasma may be formed in the processing region while the powder 300 is suspended in the processing region or passes through the processing region. The plasma treatment may be performed based on hydrogen supplied with a carrier gas, such as argon or helium, for generating the plasma, and the hydrogen may constitute a percentage material in the gas mixture.

At operation 205, method 200 may include delivering the powder to the processing region of the processing chamber, such as processing chamber 100 described above, or other chambers that may include components as described above. The powder 300 may include a plurality of individual particles. The particles making up the powder 300 may be any type of particle and may be a ceramic-containing powder in embodiments. For example, the particles of powder 300 may be or include, but are not limited to, aluminum oxide (Al₂O₃), yttrium oxide (Y₂O₃), magnesium oxide (MgO), titanium oxide (TiO₂), aluminum nitride (AlN), or silicon nitride (Si₃N₄), or any combination thereof.

During method 200, the powder may be suspended in the processing region. As described in reference to FIG. 1, suspending the powder 300 may include rotating a chamber body of the deposition system, such as chamber body 102 of FIG. 1, to repeatedly pass the powder 300 through the processing region. In some cases, the powder 300 may be suspended by controlled gas flow to form a fluidized bed.

In some embodiments, method 200 may optionally include oxidizing the powder 300 at optional operation 210. Optional operation 210 may include introducing oxygen into the processing region of the chamber. Introducing oxygen into the processing region as part of plasma enhanced deposition may permit the formation of a controlled oxide layer on the powder 300. In contrast to the passivation layer 305, the controlled oxide layer may be formed under controlled conditions, such as in an oxygen plasma in the processing region, such that an oxide layer may be formed on the powder 300 with a characteristic and uniform thickness. Additionally or alternatively, optional operation 210 may include thermal oxidation of the powder 300 subsequent removal of the passivation film 305. A surface oxide layer may impart improved control of thermal, mechanical, and/or chemical properties in a sintered material formed using the powder 300, for example, by acting as a diffusion barrier or by defining grain boundaries in the sintered material. In this way, it may be advantageous to reduce the powder 300 to remove the passivation layer 305, and subsequently to oxidize the powder 300 under controlled conditions to reform an oxide layer.

Subsequent oxidizing the powder 300 at optional operation 210, method 200 may include forming a layer of material 315 on the powder 300 at operation 215. In some embodiments, forming the layer of material 315 on the powder 300 may include undertaking operations of an atomic layer deposition (ALD) process, whereby the grains of the powder 300 may be uniformly coated. For example, operation 215 may include introducing plasma effluents to the processing region. Plasma effluents may be or include plasma generated species that are formed by a remote plasma system, such as remote plasma system 108 of FIG. 1, in communication with the processing region. Introducing the plasma effluents may include introducing a carrier gas including the plasma effluents. In this way, introducing the plasma effluents into the processing region may expose the powder 300 to plasma effluents of one or more precursors that have been subjected to plasma decomposition. Plasma effluents, therefore, may be or include ions, activated radicals, metastable species, and other decomposition products, and may be characterized by average energy distribution lower than that of a direct plasma system. Exposing the powder 300 to the plasma effluents may, in turn, result in the formation of an adsorbed monolayer of plasma effluents on the surface of the grains of the powder 300 that serves as a precursor to the formation of the layer of material 315.

In a second operation of atomic layer deposition, the plasma effluents of the first precursor may be removed from the processing region by purging the processing region of gas, while retaining the powder 300 bearing the adsorbed monolayer. Purging the processing region may be implemented using a gas removal system, such as the gas removal system 112 of FIG. 1. Subsequent purging, a second precursor may be decomposed into second plasma effluents, such that the powder 300 is exposed to the second plasma effluents. The second precursor may be chosen such that it decomposes into plasma generates species that react with the monolayer adsorbed on the powder 300 to form the layer of material 315. Subsequent forming the layer of material 315, the unreacted plasma effluents and reaction byproducts may be removed by the gas removal system.

In some embodiments, the first and second precursors may be selected such that the layer of material 315 may be or include a corrosion-resistant additive to improve the mechanical properties of a sintered material formed by sintering the powder 300. In this way, one precursor may be or include a metal and the other precursor may be or include oxygen or nitrogen. The metal may be or include, for example, a rare earth element or a transition metal. For example, one of the precursors may include the metal, such as aluminum, yttrium, magnesium, titanium, erbium, lanthanum, scandium, or zirconium. The other precursor may include oxygen or nitrogen source and may be, for example, steam (H₂O), hydrogen peroxide (H₂O₂), oxygen (O₂), oxygen-based plasma, ozone (O₃), nitrous oxide (N₂O), molecular nitrogen (N₂), ammonia (NH₃), hydrazine (N₂H₄), or nitrogen-based plasma. Based on the precursors used, the layer of material 315 may be an oxide, a nitride, or an oxynitride. For example, the layer of material 315 may be or include, but is not limited to, aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), zirconium oxide (ZrO₂), aluminum nitride (AlN), silicon nitride (SiN), tantalum nitride (TaN), titanium nitride (TiN), or zirconium nitride (ZrN). In embodiments, the layer of material 315 may include multiple different oxide or nitride materials. For example, multiple layers of material may be formed on the powder 300.

In some embodiments, either the first precursor or the second precursor may include fluorine, or other low melting point materials. For example the fluorine-containing precursor may include, but is not limited to, aluminum fluoride (AlF₃), yttrium fluoride (YF₃), magnesium (MgF₂), titanium (TiF₄), erbium (ErF₃), lanthanum (LaF₃), scandium (ScF₃), or zirconium (ZrF₄). As discussed below, the powder 300 may be sintered to form a component for semiconductor processing. The use of fluorine in the powder 300 may allow the sintering of the powder 300 to proceed with increased efficiency due to the low melting point of the fluorine present in the layer of material 315.

In some embodiments, the constituent operations of the operation 215 may be repeated to deposit multiple monolayers, such that the layer of material 315 may be formed on a monolayer-by-monolayer basis, and the thickness of the layer of material 315 may be an integer multiple of the monolayer thickness and the number of repetitions of the operation 215. Furthermore, following operation 215, a second layer of material 320 may be formed overlying the layer of material 315, by repeating the operation with either the same set of first and second precursors or a different set of first and second precursors. For example, where the layer of material 315 may be or include aluminum oxide, the second material 320 may be or include a different oxide, such as yttrium oxide, magnesium oxide, aluminum nitride, or another metal oxide or metal nitride. As such, a coated powder formed from the powder 300 by the method 200 may include a controlled oxide layer, the layer of material 315, and one or more additional layers of different materials, such as the second layer of material 320.

A flowrate of the precursors introduced to the chamber may depend at least in part on one or more parameters of the chamber, the powder 300, or the method 200. For example, where the flowrate may be such that a plasma may form with a sufficient energy density or species density, such as ions, free electrons, or activated precursor, to facilitate, for example, reduction of the passivation layer 305 or deposition of the layer of material 315. In contrast, the flowrate of precursors may be limited by entrainment of the powder 300 in the flow, which may occur when the flowrate is excessively high. In such cases, the precursors may entrain the powder 300 and carry it out of the processing region, which is to be avoided.

Related to the flowrate of the precursors, a pulse size of the first precursor or of the second precursor may be less than or about 75 minutes. At times greater than 75 minutes, the powder 300 may be fully saturated and no longer accept the precursor to form a monolayer of material. Accordingly, the pulse size of the first precursor or of the second precursor may be less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, or less.

Similarly a pulse size of the purge gas to purge the first precursor may be less than or about 120 minutes, such as less than or about 110 minutes, less than or about 100 minutes, less than or about 90 minutes, less than or about 80 minutes, less than or about 70 minutes, less than or about 65 minutes, less than or about 60 minutes, less than or about 55 minutes, less than or about 50 minutes, less than or about 45 minutes, less than or about 40 minutes, less than or about 35 minutes, less than or about 30 minutes, less than or about 25 minutes, less than or about 20 minutes, less than or about 15 minutes, less than or about 10 minutes, less than or about 5 minutes, less than or about 2 minutes, less than or about 1 minute, or less. The purge may be a longer duration than the precursor in order to ensure the precursors are fully removed from the processing region.

During method 200, such as during operation 215, a temperature within the processing chamber may be maintained at less than or about 700° C. While higher temperatures may be employed, ALD depositions may be operated at temperatures less than or about 700° C., such as less than or about 675° C., less than or about 650° C., less than or about 625° C., less than or about 600° C., less than or about 575° C., less than or about 550° C., less than or about 525° C., less than or about 500° C., less than or about 480° C., less than or about 460° C., less than or about 440° C., less than or about 420° C., less than or about 400° C., less than or about 380° C., less than or about 360° C., less than or about 340° C., less than or about 320° C., less than or about 300° C., less than or about 280° C., less than or about 260° C., less than or about 240° C., less than or about 220° C., less than or about 200° C., less than or about 180° C., less than or about 160° C., less than or about 140° C., less than or about 120° C., less than or about 100° C., less than or about 80° C., less than or about 60° C., less than or about 40° C., less than or about 20° C., or less.

Additionally, during method 200, such as during operation 215, a pressure within the processing chamber may be maintained at less than or about 50 mTorr. Again, while higher pressures may be employed, ALD depositions may be operated at pressures less than or about 50 mTorr, such as less than or about 45 mTorr, less than or about 40 mTorr, less than or about 35 m Torr, less than or about 30 mTorr, less than or about 25 mTorr, less than or about 20 mTorr, less than or about 15 mTorr, less than or about 10 mTorr, less than or about 7 mTorr, less than or about 5 mTorr, less than or about 3 mTorr, less than or about 1 mTorr, or less.

The layer of material 315 may be formed to a thickness of less than or about 3000 nm, such as less than or about 2750 nm, less than or about 2500 nm, less than or about 2250 nm, less than or about 2000 nm, less than or about 1750 nm, less than or about 1500 nm, less than or about 1250 nm, less than or about 1000 nm, less than or about 750 nm, less than or about 500 nm, less than or about 250 nm, less than or about 100 nm, or less. In embodiments, depending on the application, the layer of material 315 may be formed to a much smaller thickness, such as less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 5 nm, less than or about 2 nm, less than or about 1 nm, or less. At thicknesses greater than 3000 nm, the layer of material 315 may make sintering the powder 300 more difficult due to the increased presence of material between the powder 300.

At optional operation 220, the method 200 may include annealing the powder 300. Annealing the powder 300 at optional operation 220 may alter the crystallinity of the layer of material 315 or may further enhance the thermal, mechanical, and or chemical properties of the layer of material 315. For example, the layer of material 315 may be formed as an amorphous structure, but the anneal at optional operation 220 may cause the layer of material 315 to transition to a crystalline structure. The powder 300 may be annealed in an oxygen-containing environment, in an inert environment, or in an active gas environment. In embodiments, the active gas environment may include but is not limited to, for example, a fluorine-containing environment. The fluorine-containing environment may include, but is not limited to, diatomic fluorine (F₂). In embodiments, the powder 300 may be annealed at a temperature greater than or about 300° C., such as greater than or about 350° C., greater than or about 400° C., greater than or about 450° C., greater than or about 500° C., greater than or about 550° C., greater than or about 600° C., greater than or about 650° C., greater than or about 700° C., or more, which may be greater than the temperature at operation 215. During optional operation 220, the pressure may be controlled, and the pressure may be maintained greater than, less than, or at about atmospheric pressure.

The method 200 and its constituent operations may provide one or more improvements to plasma enhanced deposition processes for depositing materials layers onto a powder by ALD. For example, the method 200 may provide a coated powder characterized by a core shell structure, where the core may be or include a ceramic material, such as aluminum nitride or any other ceramic material, with one or more shells, such as a transition metal oxide or a rare earth oxide. The shells may be precisely deposited, due to the layer-wise deposition of atomic layer deposition methods, such that the relative composition of the coated powder may be specified by repeating the operation 215 for a predetermined number of times. Furthermore, plasma removal of a native passivation layer 305 may improve control of surface chemistry and therefore improves the thermal, mechanical, and/or chemical properties of sintered materials formed using coated powders.

As described below, the coated powder may be prepared to provide improved thermal, mechanical, and/or chemical properties to a material formed by sintering or pressing the coated powder. To that end, the method 200 may be implemented to prepare multiple coated powders, to be combined into a sintering mix. For example, a first coated powder may be or include an aluminum nitride powder coated by a layer of yttrium oxide. A second coated powder may be or include an aluminum nitride powder coated by a layer of titanium oxide. The sintering mix may then be prepared by blending the first coated powder and the second coated powder, such that a sintered material formed using the sintering mix may be characterized by improved thermal, mechanical, and/or chemical properties, due in part to the improved control of relative composition of the coating material and in part to the improved distribution of the coating material in the sintering mix. Distribution of the coating material may be improved, in particular, relative to bulk powder blends that may undergo agglomeration or density segregation, as examples of phenomena that may limit the effectiveness of blending and negatively impact the material properties of sintered materials.

At optional operation 225, the method 200 may include sintering the powder 300, or sintering mix, to form a component for semiconductor processing. As will be described further with regard to FIG. 4, the component for semiconductor processing may be, but is not limited to, a lid, a nozzle, a face plate, a gas distribution plate, a heater, a screw, a substrate support, a support platen, a liner, an edge ring, a process kit ring, or a lift pin. These components are commonly exposed to corrosive plasma conditions and may require corrosion-resistant coatings. By using coated powders previously discussed, the corrosion-resistant material may be incorporated within the component for semiconductor processing and, therefore, provide increased corrosion resistance.

FIG. 4 show schematic views of an exemplary plasms processing system including one or more components formed by the method according to some embodiments of the present technology. FIG. 4 further illustrates details relating to a semiconductor processing system 400, and one or more components that may be incorporated into system 400 that may be or include a sintered material. The sintered material, in turn, may be formed by sintering a coated powder, such as the coated powder prepared by the method 200. System 400 is understood to include any feature or aspect of a semiconductor processing chamber, and may be used to perform semiconductor processing operations including deposition, removal, and cleaning operations. System 400 may show a partial view of the chamber components being discussed and that may be incorporated in a typical semiconductor processing system, and may illustrate a view across a center of the pedestal and gas distributor, which may otherwise be of any size. Any aspect of system 400 may also be incorporated with other processing chambers or systems as will be readily understood by the skilled artisan.

System 400 may include a semiconductor processing chamber 450 including a showerhead 405, through which precursors 407 may be delivered for processing, and which may be configured to form a plasma 410 in a processing region between the showerhead 405 and a pedestal or substrate support 415. The showerhead 405 is shown at least partially internal to the chamber 450, and may be understood to be electrically isolated from the chamber 450. In this way, the showerhead 405 may act as a live electrode or as a reference ground electrode of a direct plasma system to expose a substrate held on the substrate support 415 to plasma generated species. The substrate support 415 may extend through the base of the chamber 450. The substrate support 415 may include a support platen 420, which may hold a semiconductor substrate 430 during deposition or removal processes used to form patterned structures on the semiconductor substrate 430.

The support platen 420 may be or include a sintered material formed from coated powder prepared in accordance with embodiments of method 200. The support platen 420 may incorporate embedded electrodes to provide the electrostatic field employed to hold the semiconductor substrate, and may also include a thermal control system that may facilitate processing operations including, but not limited to, deposition, etching, annealing, or desorption. In some embodiments, the support platen 420 may incorporate a plate, a perforated plate, a mesh, a wire screen, or any other distributed arrangement of conductive elements. The embedded electrodes may be or include a tuning electrode to provide further control over the plasma 410, for example, by adjusting an electric field near the surface of the support platen. Similarly, a bias electrode and/or an electrostatic chucking electrode, may be coupled with the support platen 420. The bias electrode may be coupled with a source of electric power, such as a DC power, pulsed DC power, RF bias power, a pulsed RF source or bias power, or a combination of these or other power sources. In this way, the substrate support 415 and the support platen 420 may be used during plasma processing operations not only to hold the semiconductor substrate 430, but also to tune the conditions of the plasma 410. Tuning the conditions of the plasma may include implementing automatic impedance matching to maintain plasma conditions during plasma processing operations, for example, while the composition of the plasma 410 is varied or as the surface of the semiconductor substrate 430 changes, for example, due to deposition of dielectric films onto electrode surfaces. In this way, precise control of the plasma 410 may depend on the material properties of the substrate support 415 and the support platen 420.

In some cases, the support platen 420 or other chamber components may be formed from a sintered material. For example, a powder may be pressed into a mold and heated until grains of the powder fuse into the sintered material. Subsequent operations, such as annealing, machining, incorporating electrical components, and applying protective surface coatings, may be applied to finish the component, providing a working component that can be incorporated in a plasma system. An advantage of using a sintered material may include that a finished component may serve as a refractory conductor, with favorable thermal deformation characteristics and chemical resistance to plasma etching, as well as electrical conductivity.

Advantageously, sintered material formed from a coated powder prepared by the operations of the method 200, as described in reference to FIG. 2, may exhibit improved thermal, mechanical, and/or chemical properties at temperatures employed for plasma processing operations. For example, where a conventional sintered material may be formed from a blend of powders including a ceramic, incorporation of metal oxide or a rare earth oxide for corrosion resistance may be formed on a surface of the sintered material. In this way, the resulting sintered material may include a corrosion-resistant coating may be present only on a surface of the sintered material. Over time and over the course of semiconductor processing, the corrosion-resistant coating may be deteriorated and may eventually expose the underlying sintered material. For example, a portion of the corrosion-resistant coating at one location on the sintered component may be deteriorated and completely removed, while other locations of the corrosion-resistant coating may be relatively unbothered. However, the plasma environment may attack the uncoated portion of the sintered component and erode the sintered component. This erosion may damage the sintered component as well as introduce contaminants into the processing region.

In contrast, sintering the coated powders described in reference to FIG. 3, having one or more shells formed by the operations of the method 200, may result in an improved microstructure 460. By forming the sintered material with the coated powder, the core-shell structure may serve to control the distribution of the corrosion-resistant coating. The controlled distribution, in turn, may limit the migration of the corrosion-resistant coating during sintering, and may produce two principle phases in the microstructure 460. The microstructure 460 may include a primary phase 470 and a secondary phase 480, but may be substantially free of conductive grain inclusions. For example, the primary phase 470 may define a three-dimensional network of grain boundaries, and the secondary phase 480 may be confined to the grain boundaries. The primary phase 470 may be or include a ceramic material, such as that of the powder 300 of FIG. 3. The secondary phase 480 may be or include the material of the layers formed at operation 215 of FIG. 2 that has reacted with material of the powder core to form a layer of material, such as that of the layer of material 315 of FIG. 3. For example, where the core of the coated powder is aluminum nitride and the shell includes yttrium oxide, the secondary phase 480 may be or include yttrium aluminum oxide.

Advantageously, where the microstructure 460 confines the secondary phase 480 to the grain boundaries between grains of the primary phase 470, the sintered material may include the secondary phase 480 throughout the sintered material, which may be a component for semiconductor processing, such as the support platen 420 described previously, or other components, such as a lid, a nozzle, a face plate, a gas distribution plate, a heater, a screw, a substrate support, a liner, an edge ring, a process kit ring, or a lift pin. In this way, the secondary phase 480 may be distributed throughout the sintered material. Accordingly, the secondary phase 480, such as a corrosion-resistant material, may be present within and around the sintered material. Consequently, enhanced corrosion resistance through incorporation of corrosion-resistant material may be afforded compared to conventional technologies of coating sintered components with corrosion-resistant material.

Advantageously, forming the sintered material from the coated powder may permit the composition of the sintered material to be precisely controlled. In materials formed by sintering a blend of two powders, the composition may depend on precise measurement and handling of the blend prior to sintering. In contrast, a coated powder may be formed to have a precise composition, due in part to the precise nature of ALD techniques that form single layers of a coating material for each deposition cycle. In this way, each grain of the coated powder may include a precise quantity of a layer of material on the surface, providing a sintered material with a controlled composition that may be selected to impart improved thermal, mechanical, and chemical properties to the sintered materials.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A processing method comprising:
providing a powder to a processing region of a processing chamber;
providing one or more deposition precursors to the processing region;
generating plasma effluents of the one or more deposition precursors; and
depositing a layer of material on the powder in the processing region, wherein the layer of material comprises a corrosion-resistant material, and wherein a temperature within the processing chamber is maintained at less than or about 700° C.

2. The processing method of claim 1, wherein the powder comprises a ceramic-containing powder.

3. The processing method of claim 1, wherein the powder comprises aluminum oxide (Al₂O₃), yttrium oxide (Y₂O₃), magnesium oxide (MgO), titanium oxide (TiO₂), aluminum nitride (AlN), or silicon nitride (Si₃N₄).

4. The processing method of claim 1, wherein the layer of material comprises an oxide.

5. The processing method of claim 4, wherein the oxide comprises aluminum oxide (Al₂O₃), yttrium oxide (Y₂O₃), magnesium oxide (MgO), titanium oxide (TiO₂), erbium oxide (Er₂O₃), lanthanum oxide (La₂O₃), scandium oxide (Sc₂O₃), or zirconium oxide (ZrO₂).

6. The processing method of claim 1, wherein the layer of material comprises a nitride.

7. The processing method of claim 6, wherein the nitride comprises aluminum nitride (AlN), silicon nitride (SiN), tantalum nitride (TaN), titanium nitride (TiN), or zirconium nitride (ZrN).

8. The processing method of claim 1, further comprising:
subsequent to depositing the layer of material, annealing the powder.

9. The processing method of claim 8, wherein the powder is annealed in a pressure-controlled oxygen-containing environment, inert environment, or active gas environment.

10. The processing method of claim 1, further comprising:
subsequent to depositing the layer of material, sintering the powder to form a component for semiconductor processing.

11. The processing method of claim 10, wherein the component for semiconductor processing comprises a lid, a nozzle, a face plate, a gas distribution plate, a heater, a screw, a substrate support, a support platen, a liner, an edge ring, a process kit ring, or a lift pin.

12. A processing method comprising:
providing a ceramic-containing powder to a processing region of a processing chamber;
depositing a layer of material on the ceramic-containing powder in the processing region, wherein the layer of material is a corrosion-resistant material, and wherein depositing the layer of material comprises:
exposing the ceramic-containing powder to plasma effluents of a first precursor;
purging the processing region; and
exposing the ceramic-containing powder to plasma effluents of a second precursor, wherein the layer of material comprises reaction products of the plasma effluents of the first precursor and the plasma effluents of the second precursor; and
sintering the ceramic-containing powder to form a component for semiconductor processing, wherein the layer of material is dispersed throughout the component.

13. The processing method of claim 12, wherein the ceramic-containing powder comprises aluminum oxide (Al₂O₃), yttrium oxide (Y₂O₃), magnesium oxide (MgO), titanium oxide (TiO₂), aluminum nitride (AlN), or silicon nitride (Si₃N₄).

14. The processing method of claim 12, wherein the first precursor comprises either a metal precursor or an oxygen or nitrogen precursor, wherein the second precursor comprises either a metal precursor or an oxygen or nitrogen precursor, and wherein the first precursor and the second precursor comprise different precursors.

15. The processing method of claim 12, wherein either the first precursor or the second precursor comprises fluorine.

16. The processing method of claim 12, wherein the layer of material comprises an oxynitride.

17. The processing method of claim 12, wherein:
a temperature within the processing chamber is maintained at less than or about 700° C.; and
a pressure within the processing chamber is maintained at less than or about 50 mTorr.

18. The processing method of claim 12, wherein the layer of material is characterized by a thickness of less than or about 10 nm.

19. A sintered semiconductor component comprising:
a ceramic primary phase defining a plurality of grain boundaries; and
a secondary phase confined to the plurality of grain boundaries, wherein the secondary phase is deposited on the ceramic primary phase prior to sintering a coated powder to form the sintered semiconductor component, and wherein the secondary phase comprises a corrosion-resistant material.

20. The sintered semiconductor component of claim 19, wherein the coated powder is prepared by a process comprising:
exposing a ceramic-containing powder in a processing region to plasma effluents of a first precursor;
purging the processing region; and
exposing the ceramic-containing powder to plasma effluents of a second precursor to form a layer of material on the ceramic-containing powder, wherein the layer of material comprises reaction products of the plasma effluents of the first precursor and the plasma effluents of the second precursor, and wherein the layer of material forms the secondary phase during sintering of the coated powder.
